(19) United States
(12) Patent Application Publication
(10) Pub. No.: US 2010/0180867 A1
(43) Pub. Date: Jul. 22, 2010

(54) LEAD-ZIRCONATE-TITANATE CERAMIC HAVING TEXTURING, METHOD FOR THE PRODUCTION OF THE CERAMIC, AND USE OF THE CERAMIC

(76) Inventors: Thomas Richter, Regensburg (DE); Carsten Schuh, Baldham (DE)

Correspondence Address: King & Spalding LLP, 401 Congress Avenue, Suite 3200, Austin, TX, 78701, US

(21) Appl. No.: 12/665,102

(22) PCT Filed: Jun. 4, 2008
(86) PCT No.: PCT/EP08/56919

§ 371 Date: Dec. 17, 2009

(30) Foreign Application Priority Data
Jun. 19, 2007 (DE) 10 2007 028 094.9

(51) Int. Cl. C04B 35/468; H01L 41/24; F02M 51/00; B32B 3/00

(52) U.S. Cl. 123/472; 29/25.35; 501/137; 428/148

(57) ABSTRACT

A lead-zirconate-titanate ceramic has texturing, with textured nuclei containing barium-titanate crystallites, wherein the barium-titanate crystallites have a substantially equal crystal characteristic, including form anisotropy, and an orientation in the lead-zirconate-titanate ceramic. A method for the production of a PZT ceramic has the following steps: a) providing the barium-titanate crystallite, b) mixing the barium-titanate crystallite and a starting material of the lead-zirconate-titanate into a ceramic green body such that the barium-titanate crystallites in the green body have an orientation, and c) heat-treating the green body. The heat treatment has calcination and sintering of the piezo-ceramic composition. The barium-titanate crystallites are used in a “template grain growth process” as crystallization nuclei. The piezo-ceramic component is, for example, an ultrasonic transducer or a piezo-ceramic bender actuator. In particular, the piezo-ceramic component is a multilayer piezo actuator, which is used to actuate a fuel valve of an internal combustion engine of a motor vehicle.

### CROSS-REFERENCE TO RELATED APPLICATIONS

This application is a U.S. National Stage Application of International Application No. PCT/EP2008/056919 filed Jun. 4, 2008, which designates the United States of America, and claims priority to German Application No. 10 2007 028 094.9 filed Jun. 19, 2007, the contents of which are hereby incorporated by reference in their entirety.

### TECHNICAL FIELD

The invention relates to a lead-zirconate-titanate ceramic with texture. In addition, a method is specified for the production of the ceramic and a use for the ceramic.

### BACKGROUND

Piezo-ceramic materials based on the binary mixture system of lead zirconate and lead titanate, so-called lead-zirconate-titanate ceramic (Pb(Ti,Zr)O₃, PZT), are used in many technological areas because of their very good mechanical and piezo-electric properties, for example a high Curie temperature T_{c} of over 300° C. or high d₃₃ coefficient in large and small signal ranges. Piezo-ceramic components using these materials are, for example, bending actuators, multilayer actuators and ultrasonic transducers. These components are used in actuation applications, medical technology, ultrasound technology and automobile technology.

For the purpose of improving the piezo-electric properties of PZT, and thereby increasing the performance data of the piezo-ceramic components, PZT is doped, for example, with alkaline earth metals or rare earth metals. Since the possibilities for improvement by doping have almost been exhausted, new paths must be trodden.

One possibility for improving the piezo-electric properties consists in texturing the PZT ceramic. A textured ceramic is distinguished by the fact that the grains or crystallites in the ceramic structure have the same orientation.

A method for texturing a PZT-ceramic is described, for example, in DE 102 19 910 A1. Mono-crystalline fibers of PZT, which are to be used as the texture seeds (seeds for texture formation) form the basis for the method. These texture seeds act as templates, and form a matrix, using which the PZT crystallites of the ceramic grow in an oriented way in the course of the sintering process. This process is referred to as a “templated grain growth process” (TGG).

Until now, however, it has not proved possible to realize the texturing of PZT via monocrystalline PZT fibers as the texture seeds.

### SUMMARY

According to various embodiments, a way can be indicated in which a PZT ceramic can be textured.

According to an embodiment, a lead-zirconate-titanate ceramic with texture may have texture seeds using barium-titanate crystallites, in which the barium-titanate crystallites—have essentially the same crystal habit and anisotropic form, and—have a orientation in the lead-zirconate-titanate ceramic.

According to a further embodiment, the crystallites may be present as barium-titanate crystallite platelets and one main face of each of the barium-titanate crystallite platelets is formed by the crystallographic plane. According to a further embodiment, the crystallites may have a barium-titanate crystallite length which is selected to be in the range from 10 μm to 50 μm and in particular in the range from 10 μm to 30 μm. According to a further embodiment, the crystallites may have a crystallite height selected in the range from 2 μm to 5 μm. According to a further embodiment, the ceramic may have a proportion by volume of texture seeds which is selected to be in the range from 0.1 vol % to 10 vol % and in particular in the range from 0.5 vol % to 5 vol %. According to a further embodiment, the empirical formula for the ceramic reads as follows: Pb (Mg_{1/3}Nb_{2/3})_{0.42}(Ti_{0.638}Zr_{0.362})_{0.58}O₃.

According to another embodiment, a method for producing a lead-zirconate-titanate ceramic, may have the following method steps: a) preparation of the barium-titanate crystallites, b) combining the barium-titanate crystallites and a precursor material for the lead-zirconate-titanate to form a ceramic green body in such a way that the barium-titanate crystallites have a orientation in the green body, and c) heat treatment of the green body. According to a further embodiment, a green foil can be used as the green body. According to a further embodiment, the heat treatment may include a holding phase of approx. 2 h at 900° C. According to a further embodiment, oxidic metal compounds of the metals concerned, in powder form, can be mixed to form the precursor material. According to a further embodiment, a piezo-ceramic component with at least one piezo-element can be produced, having an electrode layer with electrode material, at least one further electrode layer with a further electrode material and at least one piezo-ceramic layer, with the lead-zirconate-titanate ceramic, arranged between the electrode layers. According to a further embodiment, use can be made of a piezo-element in which the electrode material and/or the further electrode material include(s) at least one elementary metal selected from the group: silver, copper, palladium and/or platinum. According to a further embodiment, the piezo-ceramic component with the piezo-element can be selected from the group: piezo-ceramic bending actuators, piezo-ceramic multi-layer actuators, piezo-ceramic transformers, piezo-ceramic motors and piezo-ceramic ultrasonic transducers.

According to yet another embodiment, a piezo-ceramic multi-layer actuator, produced as described above, can be used for actuating a fuel injection valve in an internal combustion engine.

### BRIEF DESCRIPTION OF THE DRAWINGS

The invention is explained in more detail below by reference to an exemplary embodiment and the associated figures. These figures are schematic, and do not represent scale illustrations.

FIG. 1 shows a cross-section from one side of a ceramic piezo-element with a textured lead-zirconate-titanate ceramic.

FIG. 2 shows a cross-section from one side of a piezo-ceramic component with numerous piezo-elements.

FIG. 3 shows an X-ray diffraction (XRD) graph of the lead-zirconate-titanate ceramic.

FIG. 4 shows the relationship between the d₃₃ coefficients for the textured PZT ceramic compared to the untextured PZT ceramic.

FIG. 5 shows small-signal coupling for textured and untextured PZT ceramics.

FIG. 6 shows the lengthening of a textured PZT ceramic compared to an untextured PZT ceramic.

FIG. 7 shows a method of preparing a ceramic green foil.

### DETAILED DESCRIPTION

According to various embodiments, a lead-zirconate-titanate ceramic with texture is specified, having texture seeds containing barium-titanate crystallites, wherein the barium-titanate crystallites have essentially the same crystal habit and anisotropic form and have a (001) orientation in the lead-zirconate-titanate ceramic.

In addition, for the purpose of achieving the object, a method is specified for the production of a lead-zirconate-titanate ceramic, with the following method steps:

a) preparation of the barium-titanate crystallites,
b) combining the barium-titanate crystallites with a precursor material of the lead-zirconate-titanate to form a ceramic green body of such a nature that the barium-titanate crystallites have a (001) orientation in the green body, and
c) heat treatment of the green body.

The barium-titanate crystallites are introduced into and orientated in the precursor material of the lead-zirconate-titanate ceramic.

The term crystal habit is to be understood as the external shape of the barium-titanate crystallites. This is the ratio of the sizes of the faces of the crystallites. For example, the crystal habit might be rod-shaped. Barium-titanate crystallites with a platelet shape are particularly suitable. In one particular embodiment, therefore, the barium-titanate crystallites are present as barium-titanate crystallite platelets. Here, one main face of each of the barium-titanate crystallite platelets is formed by the crystallographic (001) plane.

The barium-titanate crystallites used as the texture seeds are distinguished by an anisotropic form. This means that the barium-titanate crystallites have a different form in different directions. The length and height of the barium-titanate crystallites are different. This anisotropy of form makes it possible to orientate the barium-titanate crystallites in the green body.

The green body is a formed solid which, apart from the barium-titanate crystallites, includes the precursor material for the PZT. This precursor material consists, for example, of a homogeneous mixture of oxides of lead, zirconium, titanium and any doping materials which may be required, pressed together. The green body may also include an organic additive, which together with the metal oxides is worked into a slurry. The organic additive will be, for example, a binder or a dispersant. From this slurry, a green body is produced in a forming process. The green body will preferably be a green foil, which is produced by the forming process (foil extrusion). The green body produced in the forming process, with its oriented barium-titanate crystals and with the precursory piezo-ceramic composition, is subjected to a heat treatment. The heat treatment of the green body includes calcination and sintering. This results in the formation and compaction of the PZT ceramic.

According to various embodiments barium-titanate crystallites are used as texture seeds in the TGG process. In the TGG process, the barium-titanate crystallites are given the same orientation, for example during foil extrusion. This means that the crystallographic (001) planes of the lead-titanate crystallites have essentially the same orientation, i.e. parallel or almost parallel to each other. The barium-titanate crystallites aligned in this way act as crystallization seeds, on which an epitaxial growth of lead-zirconate-titanate crystals takes place in the course of the heat treatment. An oriented growth of the PZT takes place. The result is a lead-zirconate-titanate ceramic with a (001) texture. It has been found in this case that the barium-titanate crystallites are not broken down during the heat treatment and their components are not incorporated into the PZT ceramic which is forming. The barium-titanate crystallites are retained and are simply enclosed by the PZT ceramic which is forming. Consequently, the use of barium-titanate crystallites as texture seeds has virtually no effect on the inherently very good piezo-electric properties of the PZT.

In principle, barium-titanate crystallites of any arbitrary size can be used as texture seeds. Their size can be determined solely by the dimensions of the green body in which the barium-titanate crystallites are integrated. In one particular embodiment however, the barium-titanate crystallites have a barium-titanate crystallite length (edge length) which is chosen in the range from 10 μm to 50 μm. The barium-titanate crystallite length will preferably be chosen to be in the range from 10 μm to 30 μm. For example, a barium-titanate crystallite length of 20 μm. In a further embodiment, the barium-titanate crystallites have a barium-titanate crystallite height chosen in the range from 1 μm to 5 μm. The barium-titanate crystallite height will preferably be chosen to be in the range from 1 μm to 3 μm. For example, a barium-titanate crystallite height of about 2 μm.

Barium-titanate crystallites with these dimensions can be achieved, for example, by drawing them from a molten salt mixture. Subsequent reduction in size, such as would be required with the familiar Remeika process for example, is not necessary. Uniform texture seeds can be used.

Using these small dimensions ensures that the barium-titanate crystallites can act optimally as texture seeds: the barium-titanate crystallites are distinguished by a relatively large “reactive” surface, on which the epitaxial growth of the lead-zirconate-titanate crystallites can take place. This has the advantage that the volumetric proportion of the barium-titanate crystallites can be kept small. Thus the piezo-electric properties of the PZT ceramic are scarcely affected by the presence of the barium-titanate crystallites.

In one particular embodiment, the lead-zirconate-titanate ceramic has texture seeds with a volumetric proportion chosen in the range from 0.1 vol % to 10 vol %, and in particular in the range from 0.5 vol % to 5 vol %. Here, larger volumetric proportions are also possible. A volumetric proportion in the lower ranges specified is therefore possible in particular if—as described above—small and hence highly reactive barium-titanate crystallites with small dimensions are used as the texture seeds.

According to various embodiments, it is possible to achieve any required lead-zirconate-titanate ceramic with texture. The lead-zirconate-titanate ceramic can have any required doping. With the aid of the doping, it is possible to optimize the composition of the lead-zirconate-titanate ceramic in relation to its usage. One example of the empirical formula for the ceramic reads as follows: Pb(Mg_{1/3}Nb_{2/3})_{0.42}(Ti_{0.638}Zr_{0.362})_{0.58}O₃.

In accordance with one particular embodiment of the method, a mixture is made in powder form of oxidic metal compounds of the metals required in the lead-zirconate-titanate.

Here, apart from oxides of the metals, such as lead oxide (PbO), zirconium oxide (ZrO₂) and titanium oxide (TiO₂), it is also possible to use precursors of the oxides of the metals, for example carbonates or oxalates. Both types of metal compound, that is the precursors of the oxides and the oxides themselves, can be referred to as oxidic metal compounds.

The powder of oxidic metal compounds can be produced in accordance with familiar methods, for example in accordance with the sol-gel, citrate, hydrothermal or oxalate methods. Here, oxidic metal compounds can be produced containing one type of metal only. It is also conceivable, in particular, that oxidic metal compounds of several types of metal are used (mixed oxides). In accordance with one particular embodiment therefore, a piezo-ceramic precursor composition is used which has at least one oxidic metal compound of at least two of the metals. An example of this is zirconate-titanate ((Zr,Ti)O₄). For the preparation of this mixed oxide it is also possible to fall back on the above-mentioned precipitation reactions. A mixed oxide method is also conceivable. In this, oxides of the metals in powder form are mixed together and calcined at high temperature. The mixed oxide is formed during the calcination.

The processing of the metal oxides and their transformation into the lead-zirconate-titanate ceramic can be effected in various ways. It is, for example, conceivable that the powder of oxidic metal compounds is first mixed until homogeneous. The result is the precursory piezo-ceramic combination in the form of a homogeneous mixture of the metal oxides. Together with the barium-titanate crystallites, this homogeneous mixture is further processed to form the green body. Following this, the green body with its precursory piezo-ceramic combination is transformed into the PZT ceramic by heat treatment, e.g. by calcination.

Preferably, during the shaping process, a ceramic green body with an organic binder and further organic additives is produced. In the green body, the lead-titanate crystallites are oriented. The binder is removed from this ceramic green body and it is sintered. When this is done, the piezo-ceramic component with the textured lead-zirconate-titanate ceramic is produced. A multi-stage heat treatment has turned out to be especially advantageous. Thus for the development of the texture it is advantageous to carry out calcination at about 750° C. after binder removal (calcination time about 2 h). In one particular embodiment, the heat treatment includes a holding phase of about 2 h at 900° C. This enables consolidation of the green body to be achieved without excessive grain and seed growth.

In accordance with one particular embodiment, a piezo-ceramic component is produced with at least one piezo-element, having one electrode layer of an electrode material, at least one further electrode layer of a further electrode material and at least one piezo-ceramic layer, with the lead-zirconate-titanate, arranged between the electrode layers. A single piezo-element represents the smallest unit of the piezo-ceramic component. For the purpose of producing the piezo-element a ceramic green foil with the precursory piezo-ceramic composition and the texture seeds has the electrode materials printed on it. Here, the electrode materials can be the same or different. The piezo-element results from the subsequent binder removal and sintering.

In accordance with one particular embodiment, a piezo-element is used in which the electrode material and/or the further electrode material incorporates at least one selected elemental metal from the group: silver, copper, palladium and/or platinum. The piezo-ceramic material or the piezo-element, as applicable, is produced in particular by a common sintering of the precursory piezo-ceramic composition and the electrode material (cofiring). Here, the electrode material can consist of a pure metal, for example solely of silver or solely of copper. An alloy of the metals cited is also possible, for example an alloy of silver and palladium.

The sintering to form the lead-zirconate-titanate ceramic can be carried out both in a reducing and in an oxidizing sintering atmosphere. In a reducing sintering atmosphere, virtually no oxygen is present. The oxygen partial pressure will be less than 1·10⁻² mbar, and preferably less than 1·10⁻³ mbar. Sintering in a reducing sintering atmosphere allows copper to be cost-effectively used as the electrode material.

In principle, by utilizing the precursory piezo-ceramic composition, it is possible to produce any desired piezo-ceramic component using the lead-zirconate-titanate ceramic. The piezo-ceramic component will have, first and foremost, at least one piezo-element as described above. Preferably, the piezo-ceramic component will have a piezo-element selected from the group: piezo-ceramic bending actuator, piezo-ceramic multi-layer actuator, piezo-ceramic transformer, piezo-ceramic motor and piezo-ceramic ultrasonic transducer. The piezo-element will be, for example, a component in a piezo-electric bending actuator. By stacking on top of one another numerous green foils, printed on one side or both sides with electrode material, followed by binder removal and sintering, a monolithic stack of piezo-elements is produced. If the dimensioning and shaping are suitable, a monolithic piezo-ceramic multi-layer actuator results. This piezo-ceramic multi-layer actuator will preferably be used to actuate a fuel injection valve in a combustion engine. With the stacking form of arrangement of the piezo-elements it is also possible, by suitable dimensioning and shaping, to achieve a piezo-ceramic ultrasonic transducer. Ultrasonic transducers are used, for example, in medical technology or for material testing.

The following particular advantages are associated with the various embodiments:
According to an embodiment, a lead-zirconate-titanate ceramic with texture can be achieved.
Apart from the possibility of improving the piezo-electric properties of the piezo-ceramic by means of the texturing, the lead-zirconate-titanate ceramic can also be doped to further improve the properties.

The lead-zirconate-titanate ceramic has the following formula: Pb(Mg_{1/3}Nb_{2/3})_{0.42}(Ti_{0.638}Zr_{0.362})_{0.58}O₃. For the purpose of texturing the ceramic, barium-titanate crystallites in the form of platelets are used. The barium-titanate platelets have the following dimensions: length about 20 μm and height around 2 μm. The platelets are strongly anisotropic in form.

The barium-titanate platelets are produced as follows: in the first step, platelet-shaped particles of Bi₄Ti₃O₁₂ with a length of 5 μm to 20 μm and a thickness of 1 μm to 2 μm are obtained from a molten salt. After this, stochiometric quantities of BaCO₃ and TiO₂ are added from these platelets. In the molten salt, Bi is replaced by Ba. The barium-titanate platelets are formed with similar dimensional proportions.

To produce the textured PZT ceramic, the procedure is as follows: a green foil 71 is produced (FIG. 7) in a foil extrusion process (slot size approx. 90 μm). For this purpose, the barium-titanate crystallites 72 are added to the precursor composition, to the extent of 5% by volume. The shear forces arising during the foil extrusion align the barium-titanate crystallites with a (001) orientation in the foil. Several foils are stacked one on top of another and are laminated under a pressure of approx. 40 MPa, and dried at approx. 60° C.

After the drying, rectangular samples are cut out with an edge length of approx. 6 mm. The binder is removed from the samples at approx. 550° C. In the sintering process which then follows, the barium-titanate crystallites act as crystallization seeds. The lead-zirconate-titanate ceramic is formed with its texturing. Here, the sintering is a multi-stage process. Thus, the sintering temperature is held at a sintering temperature of 750° C. for a period of 2 h. This is when the calcination takes place. After this, compaction is effected over a period of 2 h at 900° C.

By this means it is possible to achieve compaction without excessive crystal growth. Subsequent sintering at higher temperatures (1150° C.) for up to 10 h leads to seed growth and the texturing.

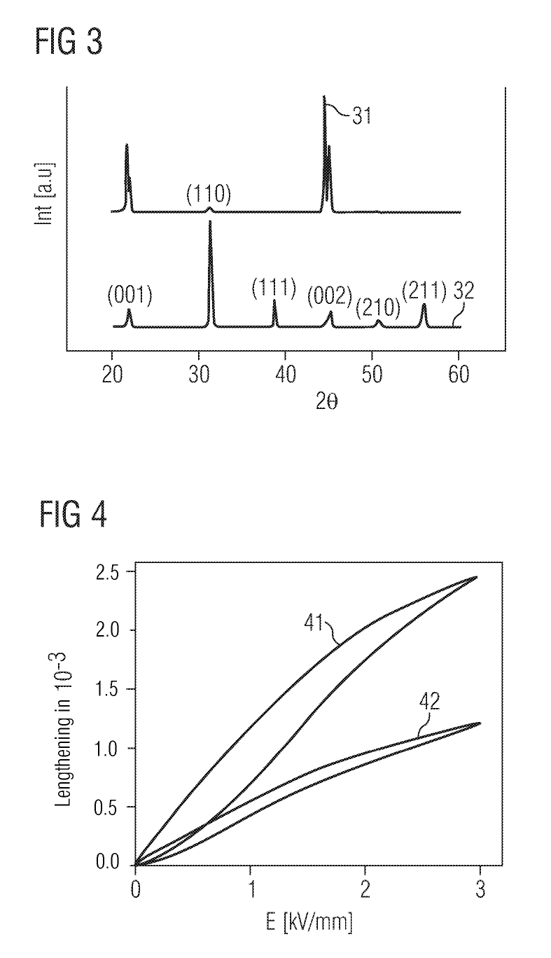

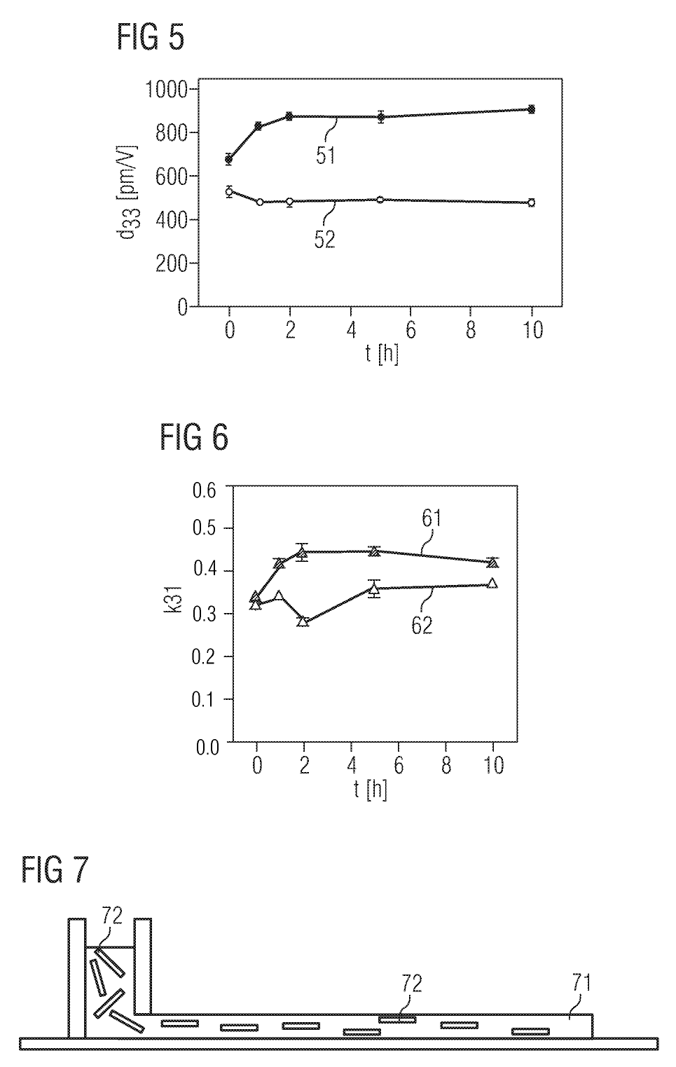

FIG. 3 shows an XRD spectrum 31 of the textured PZT ceramic. For comparison, the XRD spectrum 32 of an untextured PZT ceramic is shown. The 001 peak in the spectrum of the textured PZT ceramic emerges clearly, while the other peaks are suppressed by the texturing.

For the purpose of characterizing the dielectric properties, electrode layers of silver are affixed to the main surfaces of the samples, via which an electrical field can be applied to the ceramic, parallel to the (001) direction. FIG. 4 shows the lengthening as a function of the applied electrical field. By comparison with the untextured PZT (42), a significantly greater lengthening occurs in the case of the textured PZT (41).

In terms also of the d₃₃ coefficient (FIG. 5) and in terms of the coupling factor k₃₁, improved values appear in the case of the textured PZT (51 and 61 respectively) as against the untextured PZT (52 and 62 respectively).

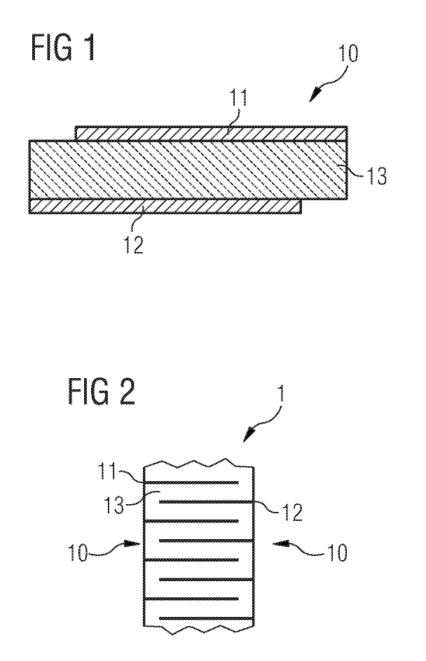

Making use of the method described, a piezo-ceramic component 1 is produced using the PZT ceramic. In accordance with a first embodiment, the piezo-ceramic component 1 is a piezo-actuator 1 with a monolithic multi-layer construction (FIG. 2). The piezo-actuator 1 consists of numerous piezo-elements 10 arranged one on top of another to form a stack (FIG. 1). Each of the piezo-elements 10 has an electrode layer 11, a further electrode layer 12 and a piezo-ceramic layer 13 arranged between the electrode layers 11 and 12. The neighboring piezo-elements 10 in the stack each have a common electrode layer. The electrode layers 11 and 12 have an electrode material comprising a silver-palladium alloy, in which the palladium content is 5% by weight. In an alternative embodiment, the electrode layers consist of (nearly) pure silver. In another alternative, the electrode material is copper.

The green foils are dried, overprinted with a paste containing the electrode material, stacked one on top of another, laminated, the binder removed and are sintered under an oxidizing sintering atmosphere (silver or silver-palladium as the electrode material) or a reducing sintering atmosphere (copper as the electrode material) to form the piezo-actuator 1.

The resulting monolithic piezo-ceramic multi-layer actuator is used to actuate a fuel injection valve in the internal combustion engine of a vehicle.

Further embodiments, not shown, such as piezo-ceramic bending actuators, piezo-ceramic transformers or piezo-ceramic ultrasonic transducers can also be achieved using the new piezo-ceramic composition.

What is claimed is:

1. Lead-zirconate-titanate ceramic with texture, comprising texture seeds using barium-titanate crystallites, wherein the barium-titanate crystallites:
have essentially the same crystal habit and anisotropic form, and
have a orientation in the lead-zirconate-titanate ceramic.

2. The ceramic according to claim 1, wherein the crystallites are present as barium-titanate crystallite platelets and one main face of each of the barium-titanate crystallite platelets is formed by the crystallographic plane.

3. The ceramic according to claim 2, wherein the crystallites have a barium-titanate crystallite length which is selected to be in the range from 10 μm to 50 μm.

4. The ceramic according to claim 2, wherein the crystallites have a crystallite height selected in the range from 2 μm to 5 μm.

5. The ceramic according to claim 1, wherein the ceramic has a proportion by volume of texture seeds which is selected to be in the range from 0.1 vol % to 10 vol %.

6. The ceramic according to claim 1, wherein the empirical formula for the ceramic reads as follows: Pb(Mg_{1/3}Nb_{2/3})_{0.42}(Ti_{0.638}Zr_{0.362})_{0.58}O₃.

7. A method for producing a lead-zirconate-titanate ceramic, having the following method steps:
a) preparation of the barium-titanate crystallites,
b) combining the barium-titanate crystallites and a precursor material for the lead-zirconate-titanate to form a ceramic green body in such a way that the barium-titanate crystallites have a orientation in a green body, and
c) heat treatment of the green body.

8. The method according to claim 7, wherein a green foil is used as the green body.

9. The method according to claim 7, wherein the heat treatment includes a holding phase of approx. 2 h at 900° C.

10. The method according to claim 7, wherein oxidic metal compounds of the metals concerned, in powder form, are mixed to form the precursor material.

11. The method according to claim 7, wherein a piezo-ceramic component with at least one piezo-element is produced, having an electrode layer with electrode material, at least one further electrode layer with a further electrode material and at least one piezo-ceramic layer, with the lead-zirconate-titanate ceramic, arranged between the electrode layers.

12. The method according to claim 7, wherein use is made of a piezo-element in which at least one of the electrode material and the further electrode material include(s) at least one elementary metal selected from the group consisting of: silver, copper, palladium and platinum.

13. The method according to claim 7, wherein the piezo-ceramic component with the piezo-element is selected from the group consisting of: piezo-ceramic bending actuators, piezo-ceramic multi-layer actuators, piezo-ceramic transformers, piezo-ceramic motors and piezo-ceramic ultrasonic transducers.

14. The ceramic according to claim 2, wherein the crystallites have a barium-titanate crystallite length which is selected to be in the range from 10 μm to 30 μm.

15. The ceramic according to claim 1, wherein the ceramic has a proportion by volume of texture seeds which is selected to be in the range from 0.5 vol % to 5 vol %.

16. A method using of a piezo-ceramic multi-layer actuator produced in accordance with the method as claimed in claim 13, the method comprising the step of actuating a fuel injection valve with said piezo-ceramic multi-layer actuator in an internal combustion engine.
